(19) United States
(12) Patent Application Publication
(10) Pub. No.: US 2026/0344257 A1
(43) Pub. Date: Oct. 29, 2026

(54) DISPLAY DEVICE AND ELECTRONIC DEVICE

(71) Applicant: Samsung Display Co., Ltd., Yongin-si (KR)

(72) Inventors: Ga Ram KIM, Yongin-si (KR); Ji Youn LEE, Yongin-si (KR); Myung Wook CHOI, Yongin-si (KR)

(21) Appl. No.: 19/657,721

(22) Filed: Apr. 24, 2026

(30) Foreign Application Priority Data
Apr. 29, 2025 (KR) 10-2025-0056641

(51) Int. Cl. H10K 59/80

(52) U.S. Cl. CPC H10K 59/873

(57) ABSTRACT

A display device and an electronic device including the display device are provided. In the display device, a first electrode layer, a first insulating layer, a second insulating layer, a second electrode layer, a third insulating layer, and a light emitting element are sequentially stacked on a substrate. A dam is located along an edge of the substrate. A first layer of the dam includes the same material as the second insulating layer. A second layer of the dam includes the same material as the third insulating layer. The first layer of the dam is located between the first electrode layer and the second electrode layer. In an area where the first layer of the dam and the second electrode layer overlap, an opening is formed in the first insulating layer.

### CROSS-REFERENCE TO RELATED APPLICATION

The present application claims priority to and the benefit of Korean Patent Application No. 10-2025-0056641, filed on Apr.29, 2025, in the Korean Intellectual Property Office, the entire content of which is incorporated herein by reference.

### BACKGROUND

### 1. Field

One or more embodiments of the present disclosure relate to a display device and an electronic device including the display device.

### 2. DESCRIPTION OF THE RELATED ART

A display device may include a large number of pixels. As the resolution of the display (of the display device) increases, the number of pixels and the number of signal lines to drive the pixels may increase significantly. In high-resolution display devices, signal lines are distributed over multiple layers.

### SUMMARY

One or more aspects of embodiments of the present disclosure are directed toward a display device and an electronic device with improved reliability.

Additional aspects and benefit of the present disclosure will be set forth in part in the description which follows and, in part, will be apparent from the description, or may be learned by practice of the presented embodiments.

According to one or more embodiments of the present disclosure, a display device includes: a first electrode layer on (e.g., located on) a substrate; a first insulating layer on (e.g., located on) the first electrode layer; a second insulating layer on (e.g., located on) the first insulating layer; a second electrode layer on (e.g., located on) the second insulating layer; a third insulating layer on (e.g., located on) the second electrode layer; a light emitting element on (e.g., located on) the third insulating layer; and a dam positioned along an edge of the substrate. The dam includes a first layer including a same material as the second insulating layer, and a second layer including a same material as the third insulating layer. The first layer of the dam is between (e.g., located between) the first electrode layer and the second electrode layer. In an area where the first layer of the dam and the second electrode layer overlap, an opening is formed in the first insulating layer.

The first insulating layer may include an inorganic material, and the second insulating layer and the third insulating layer may each include an organic material.

The first insulating layer may be removed (e.g., absent or not present) throughout an area in which the dam is located.

A taper angle of the first layer of the dam at the opening may be within a range of about 35 degrees to about 45 degrees.

The first insulating layer may be partially removed (e.g., absent) in an area where a slope of the first layer of the dam is located.

The first insulating layer may be spaced and/or apart (e.g., spaced apart or separated) from an edge of the first layer of the dam located in the opening toward an edge of the substrate by a first distance, and the first distance may be greater than or equal to a height of the first layer of the dam.

A plurality of openings may be formed in the first insulating layer in an area where the dam is located, and a total area of the plurality of openings may be at least about 50% of the area in which the dam is located.

The plurality of openings may each have a shape extending in a second direction parallel to an edge of the substrate, and may be arranged (with one another) along a first direction intersecting the second direction.

Each of the plurality of openings may have an island shape and is arranged in a matrix.

In one or more embodiments, each of the plurality of openings may have a rectangular planar shape.

In one or more embodiments, each of the plurality of openings may have a circular planar shape.

In one or more embodiments, the display device may further include: a first conductive layer on (e.g., located on) the substrate; a fourth insulating layer on (e.g., located on) the first conductive layer; a second conductive layer on (e.g., located on) the fourth insulating layer; and a fifth insulating layer on (e.g., located on) the second conductive layer, wherein the first electrode layer may be on (e.g., located on) the fifth insulating layer, wherein fan-out lines, which extend from an edge of the substrate toward a display area in which the light emitting element is located, may be in (e.g., located in) the first conductive layer, the second conductive layer, and the first electrode layer, wherein a power line, which is configured to receive (e.g., to be applied with) a constant voltage and overlap with the fan-out lines, may be in (e.g., located in) the second electrode layer, and wherein the second insulating layer may be not arranged (e.g., may be not present) between the fan-out lines and the power line.

The first insulating layer may be in (e.g., located in) an area between the dam and an edge of the substrate.

In an area between the dam and the edge of the substrate, the first insulating layer may overlap with a conductive pattern located under the first insulating layer.

According to one or more embodiments of the present disclosure, an electronic device includes a display panel configured to display an image in a display area, and a window on (e.g., located on) the display panel and including a transparent area overlapping the display area and a light shielding area around (e.g., surrounding) the transparent area. The display panel includes: a first electrode layer on (e.g., located on) a substrate; a first insulating layer on (e.g., located on) the first electrode layer; a second insulating layer on (e.g., located on) the first insulating layer; a second electrode layer on (e.g., located on) the second insulating layer; a third insulating layer on (e.g., located on) the second electrode layer; a light emitting element on (e.g., located on) the third insulating layer; and a dam that overlaps with the light shielding area. The dam includes a first layer including a same material as the second insulating layer, and a second layer including a same material as the third insulating layer. The first layer of the dam is between (e.g., located between) the first electrode layer and the second electrode layer. In an area where the first layer of the dam and the second electrode layer overlap, an opening is formed in the first insulating layer.

The first insulating layer may include an inorganic material, and the second insulating layer and the third insulating layer may each include an organic material.

The first insulating layer may be removed (e.g., absent or not present) throughout an area in which the dam is located.

A taper angle of the first layer of the dam at the opening may be within a range of about 35 degrees to about 45 degrees.

A plurality of openings may be formed in the first insulating layer in an area where the dam is located, and a total area of the plurality of openings may be at least about 50% of the area in which the dam is located.

In one or more embodiments, the display panel may further include: a first conductive layer on (e.g., located on) the substrate; a fourth insulating layer on (e.g., located on) the first conductive layer; a second conductive layer on (e.g., located on) the fourth insulating layer; and a fifth insulating layer on (e.g., located on) the second conductive layer, wherein the first electrode layer may be on (e.g., located on) the fifth insulating layer, fan-out lines, which extend from an edge of the substrate toward the display area in which the light emitting element is located, may be in (e.g., located in) the first conductive layer, the second conductive layer, and the first electrode layer, a power line, which is configured to receive (e.g., to be applied with) a constant voltage and overlap with the fan-out lines, may be in (e.g., located in) the second electrode layer, and wherein the second insulating layer may be not arranged (e.g., may be not present) between the fan-out lines and the power line.

Specific details of one or more embodiments will be included in the detailed description and drawings.

In the display device and the electronic device according to one or more embodiments of the present disclosure, enhanced reliability may be achieved by strategically modifying the structure and material composition in the dam region and adjacent layers. Specifically, in an area where the dam and the second electrode layer overlap, an opening may be formed in the first insulating layer (or passivation layer), or the passivation layer may be partially absent. This configuration helps prevent or reduce the accumulation of particles or residues—such as photoresist remnants or etching byproducts—during the patterning of the second electrode layer, which could otherwise lead to electrical shorts, leakage, or delamination. By enabling particle escape or reducing their formation, the likelihood of defect generation is reduced, thereby improving the operational stability and manufacturing yield of the device. Additionally, the dam structure, which includes a first layer made of the same material as the second insulating layer and a second layer made of the same material as the third insulating layer, acts as both a physical barrier and a stress buffer, helping to isolate the active display area from edge-related mechanical or electrical disturbances. The engineered taper angle and spacing of the dam further contribute to improved adhesion and reduced stress concentration, particularly beneficial in high-resolution or flexible display applications. Together, these design enhancements support improved electrical performance, mechanical durability, and long-term reliability of the display device. To put it another way, particles (or residues) generated during the process of forming (or patterning) the second electrode layer and defects caused by the particles may be prevented or reduced, and the stability and performance of the display device may be improved.

The aspects and/or effects of embodiments are not limited by the above examples, and one or more other aspects and/or effects are further included herein.

### BRIEF DESCRIPTION OF DRAWINGS

FIG. 1 is a schematic perspective view illustrating a display device according to one or more embodiments of the present disclosure.

FIG. 2 is a schematic exploded view illustrating an embodiment of the display device of FIG. 1 according to one or more embodiments of the present disclosure.

FIG. 3 is a schematic plan view illustrating an embodiment of the display device of FIG. 1 according to one or more embodiments of the present disclosure.

FIG. 4 is a schematic block diagram illustrating an embodiment of a sub-pixel included in the display device of FIG. 3 according to one or more embodiments of the present disclosure.

FIG. 5 is a schematic plan view in which the area EA1 of FIG. 3 is enlarged according to one or more embodiments of the present disclosure.

FIG. 6 is a schematic cross-sectional view illustrating an embodiment of a display device according to line Ⅰ-Ⅰ′ of FIG. 5 according to one or more embodiments of the present disclosure.

FIGS. 7A and 7B are each a schematic cross-sectional view illustrating an embodiment of a display device according to the line A-A' of FIG. 3 according to one or more embodiments of the present disclosure.

FIG. 8 is a cross-sectional view illustrating an embodiment in which the area EA2 of FIG. 7A is enlarged according to one or more embodiments of the present disclosure.

FIG. 9 is a schematic plan view illustrating an embodiment of a non-display area of the display device of FIG. 7A according to one or more embodiments of the present disclosure.

FIG. 10 is a cross-sectional view illustrating a comparative example of the area EA2 of FIG. 7A.

FIG. 11 is a diagram illustrating the process of forming the connecting electrode of FIG. 10.

FIG. 12 is a cross-sectional view illustrating an embodiment in which the area EA2 of FIG. 7A is enlarged according to one or more embodiments of the present disclosure.

FIGS. 13, 14, and 15, are each a schematic plan view illustrating an embodiment of a non-display area of the display device of FIG. 7A according to one or more embodiments of the present disclosure.

FIG. 16 is a block diagram of an electronic device according to one or more embodiments of the present disclosure.

FIG. 17 is a schematic diagram illustrating various electronic devices according to one or more embodiments of the present disclosure.

### DETAILED DESCRIPTION

Embodiments of the present disclosure are subject to one or more suitable modifications and may take many forms, and certain embodiments are illustrated in the drawings and described in more detail herein. However, this is not intended to limit the present disclosure to any particular disclosed form and is to be understood to include all modifications, equivalents, or substitutions that fall within the scope of the idea and technology of the present disclosure.

Terms such as "first," "second," and/or the like may be used to describe one or more suitable components, but these components are not to be limited by such terms. These terms are used only for the purpose of distinguishing one component from another. For example, a first component may be named a second component, and similarly, a second component may be named a first component, without departing from the scope of the present disclosure. The singular expression includes the plural unless the context clearly indicates otherwise. For example, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

In the present disclosure, the terms "include(s)/including," “comprise(s)/comprising,” and/or "has(have)/having" and/or the like are intended to designate the presence of the features, numbers, steps, actions, components, parts, or combinations thereof described in the disclosure, and are not to be understood as precluding the possibility of the presence or addition of one or more other features, numbers, steps, actions, components, parts, or combinations thereof. Additionally, the terms “comprise(s)/comprising,” “include(s)/including,” “have/has/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof. Further, if (e.g., when) a portion of a layer, membrane, region, plate, and/or the like is said to be "on" another portion, this includes not only embodiments in which it is "directly on" the another portion, but also embodiments in which one or more intervening elements are present therebetween. In contrast, if (e.g., when) an element is referred to as being “directly on” another element, there are no intervening element present therebetween. Furthermore, if (e.g., when) a layer, membrane, region, plate, and/or the like is said to be formed "on" another part, the direction in which it is formed is not limited to an upward direction, but includes a lateral direction or a downward direction. In addition, if (e.g., when) a layer, membrane, region, plate, and/or the like is said to be "under" another, this includes not only embodiments in which it is "directly under" the another, but also embodiments in which one or more intervening elements are present therebetween.

In the present disclosure, terms such as "about" or "approximately" include a stated value and an appropriate or suitable range of deviation from the stated value as determined by one skilled in the art, taking into account the measurement in question and the error associated with measuring a particular amount. For example, terms such as "about" or "approximately" may refer to within one or more standard deviations or within ± 30%, ± 20%, ± 10%, ± 5% of the stated value. In addition, "substantially the same" should be understood to refer to that the corresponding components are substantially identical, including any tolerances that may occur in the process. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

The advantages and features of the present disclosure, and methods of achieving them, will become apparent with reference to one or more embodiments described in more detail with reference to the accompanying drawings. However, the present disclosure is not limited to the embodiments disclosed herein, but may be implemented in a variety of other forms, and if (e.g., when) one part is referred to in the following description as being connected to another part, this includes not only direct connections, but also electrical connections with one or more other elements in between. In one or more embodiments of the present disclosure, the term "connection" between two configurations/elements may be used to include both (e.g., simultaneously) electrical and physical connections.

In the following, a display device according to one or more embodiments of the present disclosure will be described with reference to the accompanying drawings, which relate to one or more embodiments of the present disclosure.

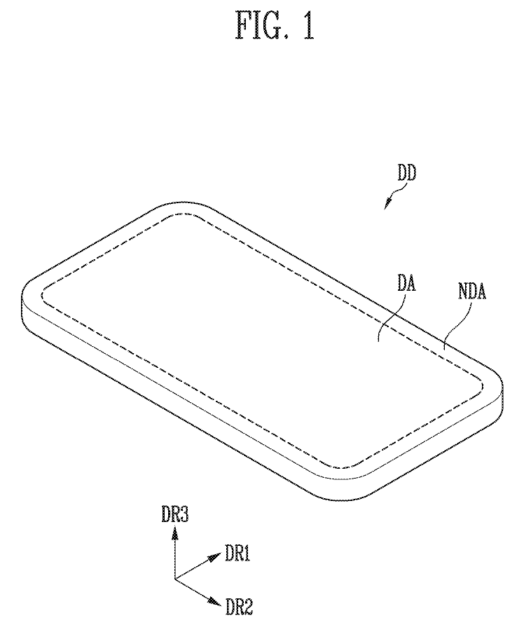

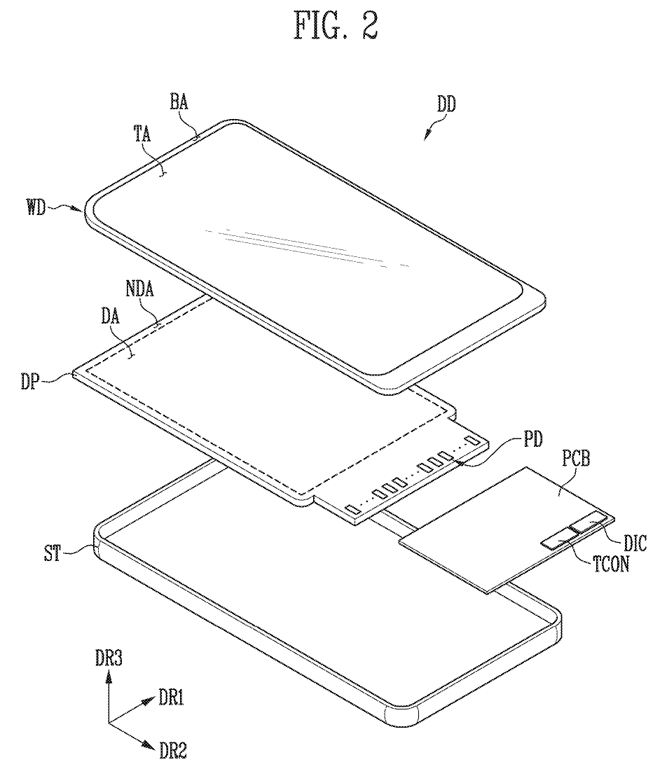

FIG. 1 is a schematic perspective view illustrating a display device according to one or more embodiments of the present disclosure. FIG. 2 is a schematic exploded view illustrating an embodiment of the display device of FIG. 1 according to one or more embodiments. FIGS. 1 and 2 and illustrate a display device DD applied to a smartphone as an example.

Referring to FIG. 1, the display device DD may display an image. The display device DD may refer to any electronic device that provides a display surface. For example, in one or more embodiments, the display device DD may include, but is not limited to, a television, a laptop, a monitor, a billboard, an Internet of Things device, a mobile phone, a smartphone, a tablet personal computer (PC), an electronic watch, a smartwatch, a watch phone, a head-mounted display, a mobile communication terminal, an electronic notebook, an e-book, a portable multimedia player (PMP), a navigation, a gaming device, a digital camera, a camcorder, and/or the like, that provides a display surface.

The display device DD may be a flat display device, a flexible display device, a curved display device, a foldable display device, a bendable display device, and/or a rollable display device. In one or more embodiments, the display device DD may be a transparent display device, a head-mounted display device, a wearable display device, and/or the like.

The display device DD may include a display area DA and a non-display area NDA. The display area DA may display an image, and in one or more embodiments, input (e.g., touch) from a user may be detected in the display area DA.

The display area DA may be parallel to a plane defined by a first direction DR1 and a second direction DR2. A normal direction of the display area DA, i.e., a thickness direction of the display device DD, is indicated by a third direction DR3. The directions indicated by the first, second, and third directions DR1, DR2, and DR3 are relative concepts and may be converted to other directions.

A shape of the display area DA shown in FIG. 1 is an example, and the shape of the display area DA may be provided and/or changed as needed without limitation.

The non-display area NDA is adjacent to the display area DA and does not display an image. In one or more embodiments, the non-display area NDA may surround (e.g., be around) the display area DA, but embodiments of the present disclosure are not limited to it. A shape of the non-display area NDA may be designed as needed. The NDA may also be referred to as a bezel area or a dead space.

Referring to FIG. 2, the display device DD may include a window WD, a display panel DP (or display module), and a housing ST (or set frame).

The window WD may protect the display panel DP from external impacts.

In one or more embodiments, the window WD may include a transmissive area TA and a bezel area BA. However, without limitation, in one or more embodiments, the window WD may further include other areas.

The transmissive area TA may be to transmit incident light. For example, the transmissive area TA may be optically transparent and have a visible light transmittance of about 90% or more. The transmissive area TA may overlap the display area DA in the third direction DR3, and an image generated by the display panel DP may pass through the transmissive area TA and be visible to a user.

The bezel area BA may be an area of relatively low light transmittance. The bezel area BA may overlap the non-display area NDA in the third direction DR3. In one or more embodiments, the bezel area BA may include an opaque material that shields light. The bezel area BA may have a certain color. In one or more embodiments, the bezel area BA may be defined by a bezel layer provided separately from a transparent substrate defining the window WD, or may be defined by an ink layer inserted into or colored by the transparent substrate. The bezel area BA may also be referred to as light shielding area.

The display panel DP may be located under the window WD.

The display panel DP may include, but is not limited to, an organic light emitting diode display panel, an inorganic light emitting diode display panel, a quantum dot light emitting display panel, and/or the like.

The display panel DP may include the display area DA and the non-display area NDA. Pixels emitting light may be arranged in the display area DA, and wiring and pads PD for providing electrical signals to the pixels may be arranged in the non-display area NDA. For example, a driver integrated circuit DIC may be mounted on a printed circuit board PCB, the printed circuit board PCB may be electrically connected to the pads PD using a conductive adhesive member (e.g., an anisotropic conductive film), and electrical signals may be provided from the driver integrated circuit DIC through the pads PD and wiring to the pixels in the display area DA. The driver integrated circuit DIC may generate the electrical signals (e.g., data signals) based on image data signals and input control signals provided from a controller TCON (or processor). In one or more embodiments, the driver integrated circuit DIC and the controller TCON may be implemented as at least one integrated circuit.

At least a portion of the housing ST may be located under the display panel DP. The housing ST may house the window WD and the display panel DP.

In FIG. 2, the entire top surface of the window WD is shown to be exposed by the housing ST, but embodiments of the present disclosure are not limited thereto. For example, in one or more embodiments, the housing ST may further include a portion protruding from a side (e.g., an upper portion of a side) of the housing ST to cover a top surface of the window WD (e.g., the bezel area BA).

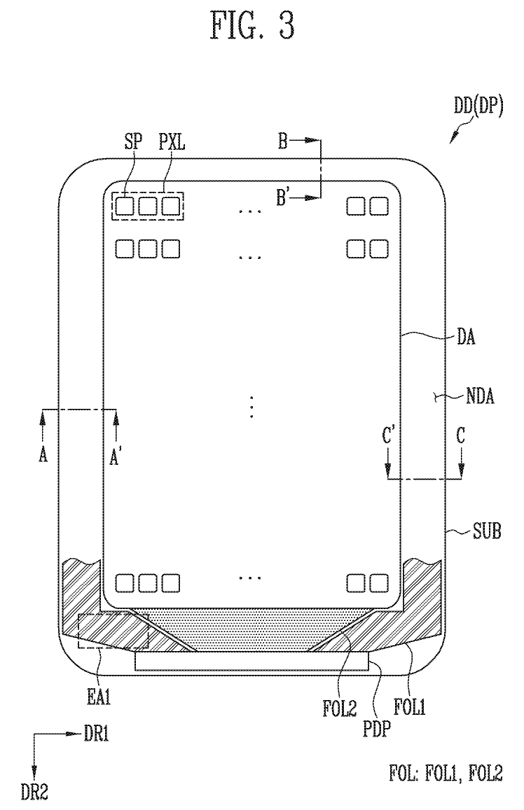

FIG. 3 is a schematic plan view illustrating an embodiment of the display device of FIG. 1 according to one or more embodiments of the present disclosure. For ease of explanation, FIG. 3 illustrates the display device DD with a focus on the display area DA, for example, a structure of a display panel DP provided on the display device DD.

Referring to FIGS. 1-3, the display panel DP may include the display area DA and the non-display area NDA.

The display area DA may be an area in which sub-pixels SP (or pixels) are provided. Each of the sub-pixels SP may include at least one light emitting element. For example, in one or more embodiments, the light emitting element may include a light emitting layer (e.g., an organic light emitting layer). The display device DD may display an image on the display area DA by driving the sub-pixels SP in response to image data.

The sub-pixels SP may be located in the display area DA of a substrate SUB. The sub-pixels SP may be arranged in a matrix form along the first direction DR1 and the second direction DR2 intersecting the first direction DR1, but the arrangement of the sub-pixels SP is not limited thereto. In one or more embodiments, at least two selected from among the plurality of sub-pixels SP may be included in a single pixel PXL displaying full color.

In the non-display area NDA of the substrate SUB, a pad portion PDP and fan-out lines FOL may be located.

The pad portion PDP may include pads PD (see FIG. 2). The pads PD may be electrically connected to the sub-pixels SP via signal lines. For example, the pads PD may be connected to the sub-pixels SP via data lines. The pad portion PDP may interface the display panel DP to other components of the display device DD. In one or more embodiments, voltages and signals desired or required for operation of the components included in the display panel DP may be provided through the pad portion PDP from the driver integrated circuit DIC (see FIG. 2).

One side of the fan-out lines FOL may be electrically connected to the sub-pixels SP located in the display area DA, and another side (e.g., the other side) of the fan-out lines FOL may be electrically connected to the pad portion PDP.

The fan-out lines FOL may include a first fan-out line FOL1 and a second fan-out line FOL2. The first fan-out line FOL1 and the second fan-out line FOL2 may be electrically isolated. The first fan-out line FOL1 and the second fan-out line FOL2 may partially overlap.

The first fan-out line FOL1 may be electrically connected to a signal line, for example, a gate line, electrically connected to the sub-pixels SP. The first fan-out line FOL1 may extend from the pad portion PDP to one area of the non-display area NDA that surrounds edges of both (e.g., simultaneously) lower sides (e.g., two lower opposite sides) of the display area DA, but embodiments of the present disclosure are not limited thereto. In one or more embodiments, the first fan-out line FOL1 may electrically connect a gate line located in the display area DA to the pad portion PDP located in the non-display area NDA.

The second fan-out line FOL2 may be electrically connected to a signal line, for example, a data line, electrically connected to the sub-pixels SP. The second fan-out line FOL2 may extend from the pad portion PDP to one area of the non-display area NDA around (e.g., surrounding) a lower edge of the display area DA, but embodiments of the present disclosure are not limited thereto. In one or more embodiments, the second fan-out line FOL2 may electrically connect a data line located in the display area DA to the pad portion PDP located in the non-display area NDA.

The first fan-out line FOL1 and the second fan-out line FOL2 may spread out in a fan shape or a spider web shape from the pad portion PDP to the display area DA in the second direction DR2, and accordingly, the non-display area NDA between the pad portion PDP and the display area DA in the second direction DR2 may be referred to as a fan-out area or a spider web area. The fan-out area or the spider web area may be an area where the printed circuit board PCB of FIG. 2 is bent to be located under the display panel DP (or the display area DA).

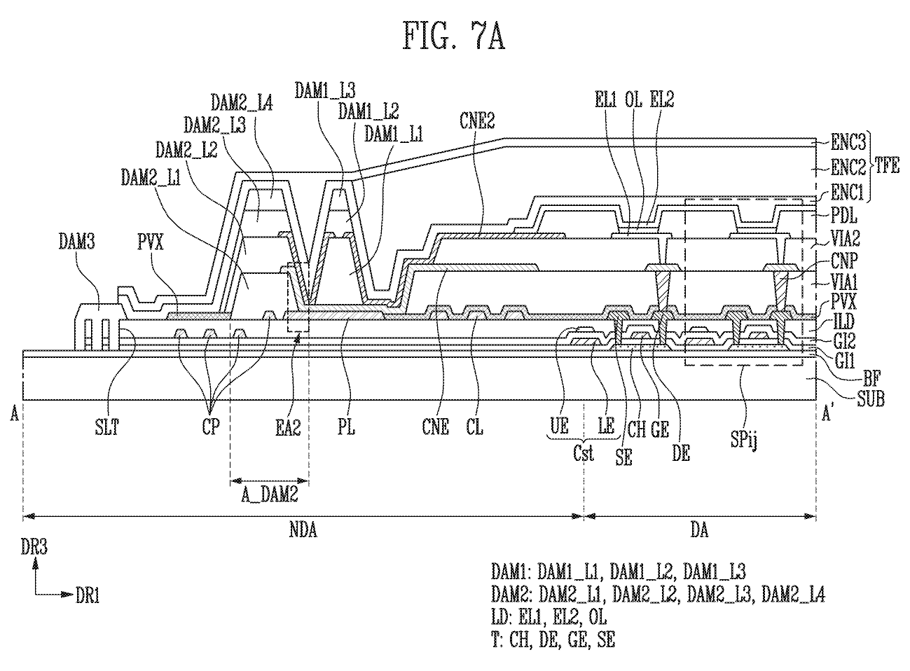

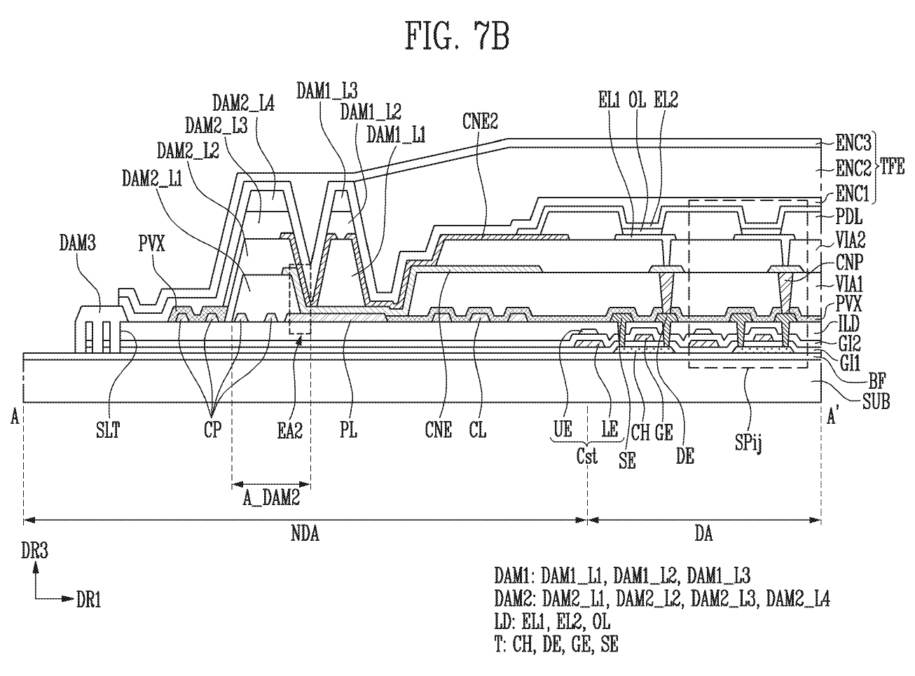

A cross-sectional structure of the display device DD along the line A-A', the line B-B', and the line C-C' will be described later with reference to FIGS. 7A and 7B .

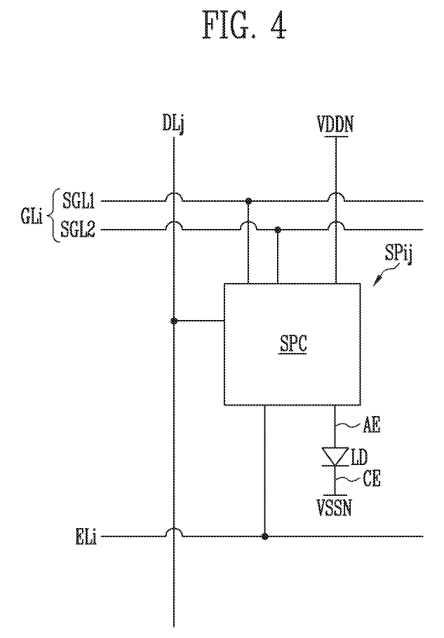

FIG. 4 is a schematic block diagram illustrating an embodiment of a sub-pixel included in the display device of FIG. 3 according to one or more embodiments of the present disclosure. In FIG. 4, an ij-th sub-pixel SPij of the sub-pixels SP of FIG. 3 arranged in an i-th row and a j-th column is shown as an example. Here, i and j may be positive integers.

Referring to FIG. 4, the ij-th sub-pixel SPij may include a sub-pixel circuit SPC and a light emitting element LD.

The light emitting element LD may be connected between a first power voltage node VDDN (or first power line) and a second power voltage node VSSN (or second power line). The first power voltage node VDDN is a node carrying a first power voltage, and the second power voltage node VSSN is a node carrying a second power voltage. The first power voltage may have a higher voltage level than the second power voltage.

An anode electrode AE of the light emitting element LD may be electrically connected to the first power voltage node VDDN via the sub-pixel circuit SPC, and a cathode electrode CE of the light emitting element LD may be electrically connected to the second power voltage node VSSN. For example, in one or more embodiments, the anode electrode AE of the light emitting element LD may be connected to the first power voltage node VDDN via one or more transistors included in the sub-pixel circuit SPC.

The sub-pixel circuit SPC may be electrically connected to signal lines. For example, the sub-pixel circuit SPC may be electrically connected to an i-th gate line GLi of gate lines, an i-th emission control line ELi of emission control lines, and a j-th data line DLj of data lines. The sub-pixel circuit SPC may be configured to control the light emitting element LD based on signals received via these signal lines.

The sub-pixel circuit SPC may operate in response to a gate signal received via the i-th gate line GLi. The i-th gate line GLi may include one or more sub-gate lines. For example, as shown in FIG. 4, in one or more embodiments, the i-th gate line GLi may include first and second sub-gate lines SGL1 and SGL2, in which case the sub-pixel circuit SPC may operate in response to gate signals received through the first and second sub-gate lines SGL1 and SGL2.

The sub-pixel circuit SPC may receive a data signal via the j-th data line DLj. The sub-pixel circuit SPC may store a voltage corresponding to the data signal in response to at least one of the gate signals received via the first and second sub-gate lines SGL1 and SGL2. In response to a light emission control signal received via the i-th light emission control line ELi, the sub-pixel circuit SPC may control a current flowing from the first power voltage node VDDN to the second power voltage node VSSN through the light emitting element LD in accordance with the stored voltage. Accordingly, the light emitting element LD may generate (or emit) light of a luminance corresponding to the data signal.

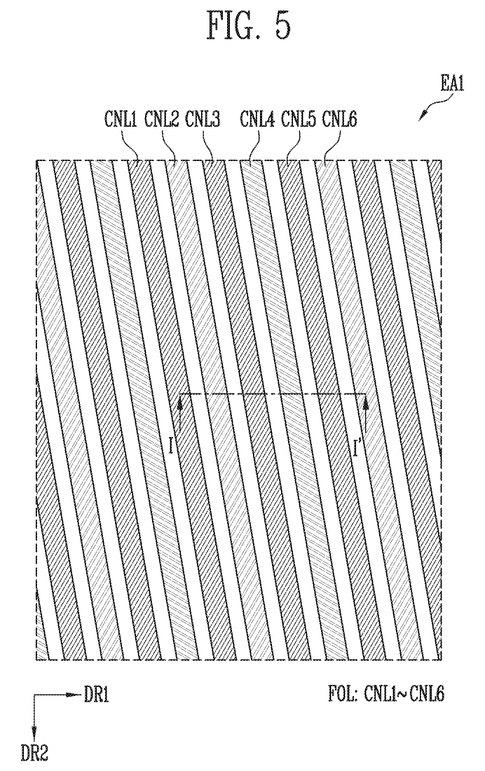

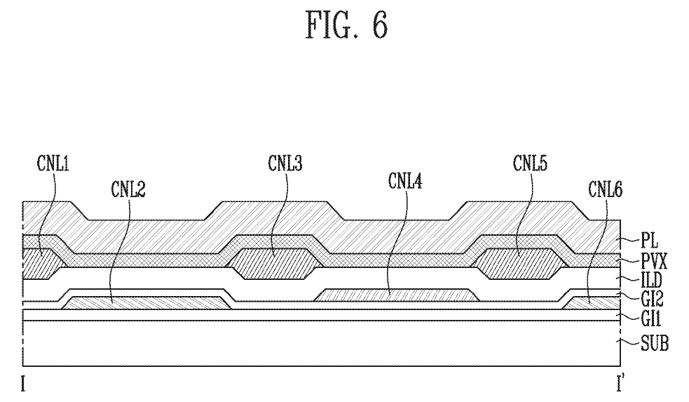

FIG. 5 is a schematic plan view in which the area EA1 of FIG. 3 is enlarged according to one or more embodiments of the present disclosure. FIG. 6 is a schematic cross-sectional view illustrating an embodiment of a display device according to the line I- I′ of FIG. 5 according to one or more embodiments.

Referring to FIG. 5, in one or more embodiments, the fan-out lines FOL may include connection lines CNL1 to CNL6. The connection lines CNL1 to CNL6 may refer to fan-out lines FOL located in a fan-out area or a spider web area.

The connection lines CNL1 to CNL6 extend in a direction intersecting the first direction DR1 and the second direction DR2 (e.g., diagonally), and may be arranged along the first direction DR1. The connection lines CNL1 to CNL6 may not be connected to one another or may be separated from one another.

In FIG. 5, the connection lines CNL1 to CNL6 are shown as not overlapping each other, but this is for the purpose of distinguishing the connection lines CNL1 to CNL6 from each other, and embodiments of the present disclosure are not limited thereto. For example, the connection lines CNL1 to CNL6 (e.g., provided in difference layers) may partially overlap with neighboring connection lines.

In one or more embodiments, the fan-out lines FOL may be located in different layers.

Referring to FIG. 6, insulating layers may be arranged on the substrate SUB.

In one or more embodiments, the substrate SUB (or base layer) may include, but is not limited to, a transparent insulating material that allows light to pass through. The substrate SUB may be a rigid substrate or a flexible substrate. In one or more embodiments, the substrate SUB may include an insulating material such as glass or a resin. The substrate SUB may have a single-layer structure or a multilayer structure.

Insulating layers may be arranged on the substrate SUB. In one or more embodiments, the insulating layers may include a first gate insulating layer GI1, a second gate insulating layer GI2, an interlayer insulating layer ILD, and a passivation layer PVX. The insulating layers are not limited thereto, and other insulating layers may be added, for example.

The first gate insulating layer GI1 may be arranged on the substrate SUB. The first gate insulating layer GI1 may include an inorganic material. For example, in one or more embodiments, the inorganic material may include at least one of silicon nitride (SiNₓ), silicon oxide (SiOₓ), silicon oxynitride (SiOₓN_{y}), or aluminum oxide (AlOₓ).

The second gate insulating layer GI2 (or fourth insulating layer) may be arranged on the first gate insulating layer GI1. The second gate insulating layer GI2 may include an inorganic material.

The interlayer insulating layer ILD (or fifth insulating layer) may be arranged on the second gate insulating layer GI2. The interlayer insulating layer ILD may include an inorganic material.

The passivation layer PVX (or first insulating layer) may be arranged on the interlayer insulating layer ILD. The passivation layer PVX may include an inorganic material or an organic material. For example, the organic material may be a polyacrylate resin, an epoxy resin, a phenolic resin, a polyamide resin, a polyimide resin, an unsaturated polyester resin, an unsaturated polyester resin, a poly-phenylene ether resin, a poly-phenylene sulfide resin, and/or a benzocyclobutene resin. In one or more embodiments, the organic material may include at least one of a poly-phenylene ether resin, a poly-phenylene sulfide resin, or a benzocyclobutene resin.

A power line PL may be arranged on the passivation layer PVX. A constant voltage may be applied to the power line PL. For example, in one or more embodiments, a first power voltage or a second power voltage described with reference to FIG. 4 may be applied to the power line PL.

In one or more embodiments, a second connection line CNL2 and a sixth connection line CNL6 may be located in a first conductive layer between the first gate insulating layer GI1 and the second gate insulating layer GI2, a fourth connection line CNL4 may be located in a second conductive layer between the second gate insulating layer GI2 and the interlayer insulating layer ILD, and a first connection line CNL1, a third connection line CNL3, and a fifth connection line CNL5 may be located in a third conductive layer between the interlayer insulating layer ILD and the passivation layer PVX. For example, even-numbered connection lines among the connection lines CNL1 to CNL6 may be alternately located in the first conductive layer and the second conductive layer, and odd-numbered connection lines among the connection lines CNL1 to CNL6 may be located in the third conductive layer. Each of the first to third conductive layers may include, but is not limited to, a metal.

Compared to a comparable embodiment utilizing only the first and second conductive layers, in an embodiment in which the connection lines CNL1 to CNL6 are distributed using the first to third conductive layers, a larger number of connection lines CNL1 to CNL6 may be arranged in the fan-out area or the spider web area, or a line width or spacing of the connection lines CNL1 to CNL6 may be sufficiently secured. The area of the non-display area NDA (or fan-out area, spider web area) for arranging the connection lines CNL1 to CNL6 or fan-out lines FOL may be reduced or prevented from becoming large. The resistance of the connection lines CNL1 to CNL6 or fan-out lines FOL may be reduced, which may improve the display quality.

For example, in one or more embodiments, a line width (e.g., width in the first direction DR1) of each of the second connection line CNL2, the fourth connection line CNL4, and the sixth connection line CNL6 may be about 5 micrometers (μm), and a spacing (e.g., spacing in the first direction DR1) between the second connection line CNL2, the fourth connection line CNL4, and the sixth connection line CNL6 may be about 1 μm. For example, the spacing between the second connection line CNL2 and the fourth connection line CNL4 may be about 1 μm, and the spacing between the fourth connection line CNL4 and the sixth connection line CNL6 may be about 1 μm. A line width of each of the first connection line CNL1, the third connection line CNL3, and the fifth connection line CNL5 may be about 3 μm, and a spacing between the first connection line CNL1, the third connection line CNL3, and the fifth connection line CNL5 may be about 3 μm. For example, the spacing between the first connection line CNL1 and the third connection line CNL3 may be about 3 μm, and the spacing between the third connection line CNL3 and the fifth connection line CNL5 may be about 3 μm. In these embodiments, the first connection line CNL1, the third connection line CNL3, and the fifth connection line CNL5 may partially overlap with the second connection line CNL2, the fourth connection line CNL4, and the sixth connection line CNL6.

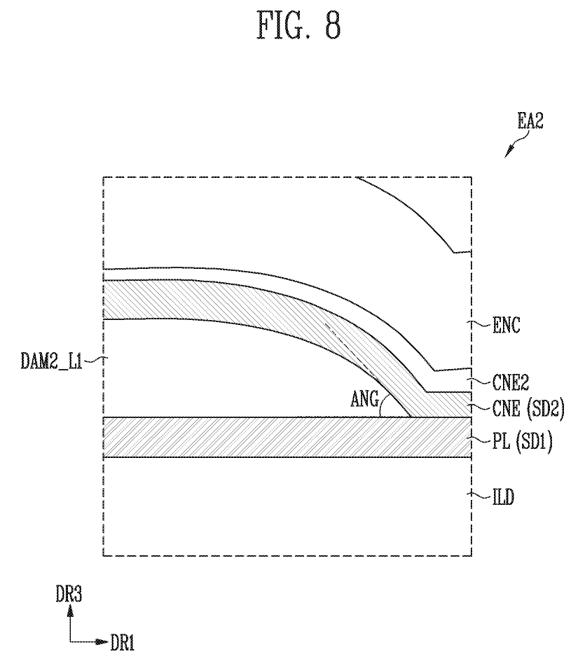

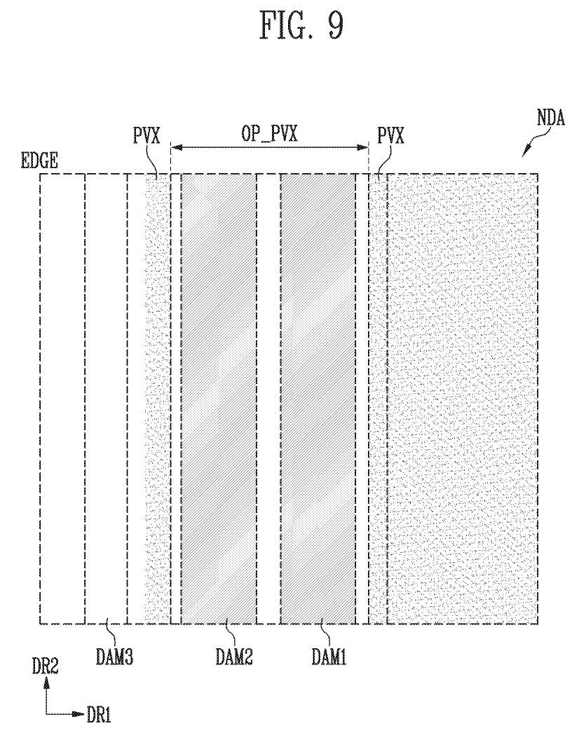

FIGS. 7A and 7B are each a schematic cross-sectional view illustrating an embodiment of a display device according to the line A-A' of FIG. 3 according to one or more embodiments of the present disclosure. FIG. 8 is a cross-sectional view illustrating an embodiment in which the area EA2 of FIG. 7A is enlarged according to one or more embodiments. FIG. 9 is a schematic plan view illustrating an embodiment of a non-display area of the display device of FIG. 7A according to one or more embodiments. Because the cross-section along the line B-B' and the cross-section along the line C-C' of FIG. 3 are each substantially the same or similar to the cross-section along the line A-A', the display device will be described with a focus on the cross-section along the line A-A'.

Referring to FIGS. 7A, 7B, and 8, a sub-pixel (e.g., ij-th sub-pixel SPij) may be provided in the display area DA. Dams DAM1 to DAM3 may be provided in the non-display area NDA. In the following, a structure in the display area DA will be described first, followed by a structure in the non-display area NDA.

The sub-pixel may include a transistor T, a light emitting element LD, and a capacitor Cst. The transistor T may be connected to a corresponding fan-out line among the fan-out lines FOL in FIG. 3, the light emitting element LD may be connected to the transistor T, and the capacitor Cst may store a data signal provided to the sub-pixel. The transistor T and the capacitor Cst may be included in the sub-pixel circuit SPC of FIG. 4. The transistor T may be a driving transistor for controlling the light emitting element LD, or a switching transistor for switching the driving transistor.

A buffer film BF may be arranged on the substrate SUB. The buffer film BF may prevent or reduce impurities from diffusing into a channel CH of the transistor T. In one or more embodiments, the buffer film BF may include an inorganic material. Depending on materials and process conditions of the substrate SUB, in one or more embodiments, the buffer film BF may not be provided.

An active layer may be arranged on the buffer film BF. The active layer may be doped and patterned, and may include the channel CH, a source region, and a drain region of the transistor T, or may constitute a wiring. The active layer may include a polysilicon semiconductor, an amorphous silicon semiconductor, or an oxide semiconductor. The channel CH may be a semiconductor pattern that is not doped with impurities and may be a true semiconductor. The source region, the drain region, and the wiring may each be a semiconductor pattern doped with impurities. The impurities may be N-type (kind) impurities or P-type (kind) impurities.

A first gate insulating layer GI1 may be arranged on the active layer and the buffer film BF and may cover the active layer. The first gate insulating layer GI1 may include an inorganic material.

A first conductive layer may be arranged on the first gate insulating layer GI1. The first conductive layer may include a gate electrode GE of the transistor T and a lower electrode LE of the capacitor Cst. The gate electrode GE may overlap the channel CH in the third direction DR3.

The first conductive layer may include a metal. For example, the metal may include gold (Au), silver (Ag), aluminum (Al), molybdenum (Mo), chromium (Cr), titanium (Ti), nickel (Ni), neodymium (Nd), and/or copper (Cu). In one or more embodiments, the first conductive layer may be formed as a single layer, but embodiments of the present disclosure are not limited thereto. For example, in one or more embodiments, the first conductive layer may be formed as multiple layers.

A second gate insulating layer GI2 may be arranged on the first conductive layer and the first gate insulating layer GI1 and may cover the first conductive layer. The second gate insulating layer GI2 may include an inorganic material.

A second conductive layer may be arranged on the second gate insulating layer GI2. The second conductive layer may include an upper electrode UE of the capacitor Cst. The lower electrode LE and the upper electrode UE may constitute the capacitor Cst. The second conductive layer may include a metal. The second conductive layer may be formed as a single-layer or multiple layers.

An interlayer insulating layer ILD may be arranged on the second conductive layer and the second gate insulating layer GI2 and may cover the second conductive layer. The interlayer insulating layer ILD may include an inorganic material.

A third conductive layer (or first electrode layer) may be arranged on the interlayer insulating layer ILD. The third conductive layer may include a source electrode SE and a drain electrode DE of the transistor T. The source electrode SE and the drain electrode DE may contact the source region and the drain region of the active layer, respectively, through contact holes penetrating the interlayer insulating layer ILD, the second gate insulating layer GI2, and the first gate insulating layer GI1. The third conductive layer may include a metal. The third conductive layer may be formed as a single-layer or multiple layers.

A passivation layer PVX may be arranged on the third conductive layer and the interlayer insulating layer ILD and may cover the third conductive layer. The passivation layer PVX may include an inorganic material.

A first via layer VIA1 (or second insulating layer) may be arranged on the passivation layer PVX. The first via layer VIA1 may include an organic material.

A fourth conductive layer (or second electrode layer) may be arranged on the first via layer VIA1. The fourth conductive layer may include a connection pattern CNP (or bridge pattern). The connection pattern CNP may be connected to the source electrode SE or the drain electrode DE of the transistor T via contact holes in the first via layer VIA1. The connection pattern CNP may include a metal.

A second via layer VIA2 (or third insulating layer) may be arranged on the first via layer VIA1 and the fourth conductive layer, and may cover the fourth conductive layer. The second via layer VIA2 may include an organic material.

A first pixel electrode layer may be arranged on the second via layer VIA2. The first pixel electrode layer may include a first electrode EL1. The first electrode EL1 may be coupled to the connection pattern CNP via contact holes in the second via layer VIA2. For example, in one or more embodiments, the first electrode EL1 may be, but is not limited to, an anode electrode of the light emitting element LD.

In one or more embodiments, the first pixel electrode layer may include a metal. In one or more embodiments, the first pixel electrode layer may include a transparent conductive material. For example, the transparent conductive material may include indium tin oxide (ITO), indium zinc oxide (IZO), zinc oxide (ZnO), or indium tin zinc oxide (ITZO).

A pixel defining layer PDL (or seventh insulating layer) may be arranged on the second via layer VIA2 and the first pixel electrode layer. The pixel defining layer PDL may compartmentalize an emission area of each sub-pixel. The pixel defining layer PDL may include an organic material. The pixel defining layer PDL may expose a top surface of the first electrode EL1 and may protrude from the substrate SUB in the third direction DR3 along the perimeter of the sub-pixel.

A light emitting layer OL may be provided in the emission area surrounded by the pixel defining layer PDL. For example, in one or more embodiments, the light emitting layer OL may be, but is not limited to, an organic light emitting layer. For example, in one or more embodiments, the light emitting layer OL may have a structure stacked with a hole injection layer (HIL), a hole transport layer (HTL), an emission layer (EML), an electron transport layer (ETL), and an electron injection layer (EIL).

A second pixel electrode layer may be arranged on the light emitting layer OL and the pixel defining layer PDL. The second pixel electrode layer may include a second electrode EL2. In one or more embodiments, the second electrode EL2 may be provided to cover most of the display area DA and may be shared by a plurality of sub-pixels. However, by way of example, in one or more embodiments, the second electrode EL2 may be provided per sub-pixel. For example, the second electrode EL2 may be a cathode electrode of the light emitting device LD, but embodiments of the present disclosure are not limited thereto. The second pixel electrode layer may include a metal or a transparent conductive material.

An encapsulation layer TFE may be provided on the second pixel electrode layer, and the encapsulation layer TFE may cover the light emitting element LD. The encapsulation layer TFE may have a single-layer structure or a multilayer structure. For example, in one or more embodiments, the encapsulation layer TFE may include a plurality of an organic layer and an inorganic layer alternately stacked on each other.

For example, in one or more embodiments, the encapsulation layer TFE may include first, second, and third encapsulation layers ENC1, ENC2, and ENC3. The first encapsulation layer ENC1 and the third encapsulation layer ENC3 may each include an inorganic material, and the second encapsulation layer ENC2 may include an organic material. The first encapsulation layer ENC1 and the third encapsulation layer ENC3 may prevent or reduce moisture and/or oxygen from entering the light emitting element LD, and the second encapsulation layer ENC2 may prevent or reduce cracking. In one or more embodiments, the first via layer VIA1, the second via layer VIA2, and the pixel defining layer PDL, each including an organic material, may not extend continuously to cover the entire of the non-display area NDA (e.g., may extend to cover a portion of the non-display area NDA) and may be covered by the first encapsulation layer ENC1.

Next, the structure of the non-display area NDA will be described. In describing the structure of the non-display area NDA, contents that have already been described will be skipped or briefly described to avoid redundancy.

The third conductive layer arranged on the interlayer insulating layer ILD may further include a control line CL, a power line PL, and a conductive pattern CP.

In one or more embodiments, the control line CL may be the first fan-out line FOL1 of FIG. 3.

The power line PL may be located on an outer side (e.g., outer area or periphery area) of the substrate SUB (or display panel), or closer to an edge of the substrate SUB than the control line CL. The power line PL may overlap a first dam DAM1 and a second dam DAM2 in the third direction DR3, but embodiments of the present disclosure are not limited thereto. The power line PL (or power electrode) may be a power line to which a second power voltage is applied as described with reference to FIG. 4. The power line PL may be electrically connected to the second electrode EL2 of the light emitting element LD via a connection electrode CNE.

The conductive pattern CP may be located outboard of the power line PL. Some of the conductive pattern CP may be located outside the second dam DAM2 (e.g., closer to the edge of the substrate than the second dame DAM2). For example, the conductive pattern CP may include the first fan-out line FOL1 in FIG. 3 or a crack detection line. For example, if (e.g., when) a crack occurs in the display panel, resistance of the crack detection line may increase. Using at least some of the conductive pattern CP, it may be determined whether a crack has occurred in the display panel. At least some of the conductive pattern CP may prevent or reduce the crack from propagating into the interior of the display panel when cutting the edge of the display panel, or may prevent or reduce external moisture and/or oxygen from penetrating into the interior of the display panel. Referring to FIG. 7B, for example, in embodiments in which layers on the conductive pattern CP are curved by at least a portion of the conductive pattern CP, external moisture and/or oxygen may have a longer penetration path.

The conductive pattern CP may be located in a same layer as the upper electrode UE of the capacitor Cst or the source electrode SE of the transistor T. For example, the conductive pattern CP may be included in the second conductive layer or the third conductive layer. At least a portion of the conductive pattern CP may overlap with the passivation layer PVX. According to one or more embodiments, as shown in FIG. 7B, the conductive pattern CP may be located in a same layer as the source electrode SE of the transistor T, and a portion of the conductive pattern CP may be covered by the passivation layer PVX. The passivation layer PVX covering a portion of the conductive pattern CP may prevent or reduce the conductive pattern CP from being defected by residues (e.g., residues from a process of forming an electrode on the passivation layer PVX).

The fourth conductive layer, which is arranged on the first via layer VIA1 and the passivation layer PVX, may further include the connection electrode CNE (or first connection electrode). The connection electrode CNE extends toward the power line PL, and may overlap the power line PL in the third direction DR3. In an area between the first dam DAM1 and the second dam DAM2, the passivation layer PVX may expose the power line PL, and the connection electrode CNE may contact the exposed portion of the power line PL. A second connection electrode CNE2 may be arranged on the second via layer VIA2. The second connection electrode CNE2 may extend toward the power line PL, may overlap the connection electrode CNE in the third direction DR3, and may contact the connection electrode CNE. The connection electrode CNE and the second connection electrode CNE2 may electrically connect the second electrode EL2 of the light emitting element LD and the power line PL.

The dams DAM1 to DAM3 may be adjacent to an edge of the substrate SUB (or display panel). Each of the dams DAM1 to DAM3 may surround the display area DA. As shown in FIG. 9, in a plan view, each of the dams DAM1 to DAM3 may extend along the edge EDGE of the substrate SUB. The second dam DAM2 may be positioned outward from the first dam DAM1, and the third dam DAM3 may be positioned outward from the second dam DAM2.

The first dam DAM1 and the second dam DAM2 may prevent or reduce liquid organic material from spilling over to an edge area of the substrate SUB during the formation of an organic layer, such as an organic layer included in the encapsulation layer TFE, for example, the second encapsulation layer ENC2.

The first dam DAM1 may include a first layer DAM1_L1, a second layer DAM1_L2, and a third layer DAM1_L3. The first layer DAM1_L1 may be located on the connection electrode CNE, the second layer DAM1_L2 may be located on the first layer DAM1_L1 and the second connection electrode CNE2, and the third layer DAM1_L3 may be located on the second layer DAM1_L2. Each of the first layer DAM1_L1, the second layer DAM1_L2, and the third layer DAM1_L3 may have a cross-sectional shape that gradually decreases in width from a bottom surface to a top surface of the first dam DAM1. For example, in one or more embodiments, each of the first layer DAM1_L1, the second layer DAM1_L2, and the third layer DAM1_L3 may have a trapezoidal cross-sectional shape.

The first layer DAM1_L1 of the first dam DAM1 may be formed by a same process as forming the second via layer VIA2 and may include a same material as the second via layer VIA2. The second layer DAM1_L2 of the first dam DAM1 may be formed by a same process as forming the pixel defining layer PDL and may include a same material as the pixel defining layer PDL. The third layer DAM1_L3 of the first dam DAM1 may include the same material as the pixel defining layer PDL.

The second dam DAM2 may include a first layer DAM2_L1, a second layer DAM2_L2, a third layer DAM2_L3, and a fourth layer DAM2_L4. The first layer DAM2_L1 may be located on the power line PL, the second layer DAM2_L2 may be located on the first layer DAM2_L1 and the connection electrode CNE, the third layer DAM2_L3 may be located on the second layer DAM2_L2 and the second connection electrode CNE2, and the fourth layer DAM2_L4 may be located on the third layer DAM2_L3. Each of the first layer DAM2_L1, the second layer DAM2_L2, the third layer DAM2_L3, and fourth layer DAM2_L4 may have a cross-sectional shape that gradually decreases in width from a bottom surface to a top surface of the second dam DAM2. For example, in one or more embodiments, each of the first layer DAM2_L1, the second layer DAM2_L2, the third layer DAM2_L3, and the fourth layer DAM2_L4 may have a trapezoidal cross-sectional shape. An organic material included in at least one layer of the second dam DAM2 may have a better bonding force with metals than the bonding force with inorganic materials. Therefore, in embodiments in which the second dam DAM2 is in contact with the power line PL (and the connection electrode CNE) including metal, the stability of the second dam DAM2 may be improved.

The first layer DAM2_L1 of the second dam DAM2 may be formed by a same process as forming the first via layer VIA1 and may include a same material as the first via layer VIA1. The second layer DAM2_L2 of the second dam DAM2 may be formed by a same process as forming the second via layer VIA2 and may include a same material as the second via layer VIA2. The third layer DAM2_L3 of the second dam DAM2 may be formed by a same process as forming the pixel defining layer PDL and may include a same material as the pixel defining layer PDL. The fourth layer DAM2_L4 of the second dam DAM2 may include the same material as the pixel defining layer PDL.

The third dam DAM3 (or crack dam) may prevent or reduce cracks that occur in the substrate SUB from propagating to the display area. For example, in one or more embodiments, in an area overlapping the third dam DAM3 in the third direction DR3, at least one slit SLT may be formed in each of the first gate insulating layer GI1, the second gate insulating layer GI2, the interlayer insulating layer ILD, and the passivation layer PVX, and the third dam DAM3 may cover the at least one slit SLT.

The third dam DAM3 may be formed by a same process as one selected among the processes forming the first via layer VIA1, the second via layer VIA2, or the pixel defining layer PDL, and may include a same material as the one. However, the formation of the third dam DAM3 is not limited thereto. For example, in one or more embodiments, the third dam DAM3 may be formed by a different process than that of the first via layer VIA1, the second via layer VIA2, and the pixel defining layer PDL.

In the non-display area NDA where the dams DAM1 to DAM3 are located, the encapsulation layer TFE may include only the first and third encapsulation layers ENC1 and ENC3 (or encapsulation layer ENC (see FIG. 8)) each formed of inorganic material.

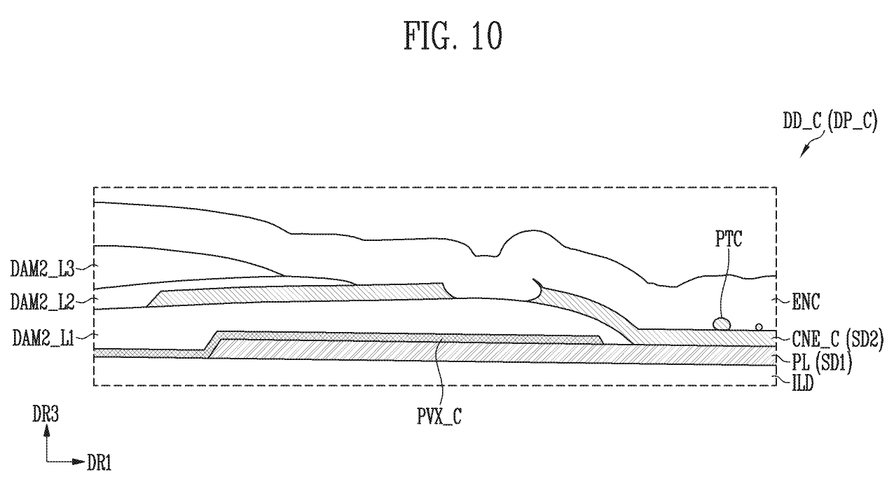

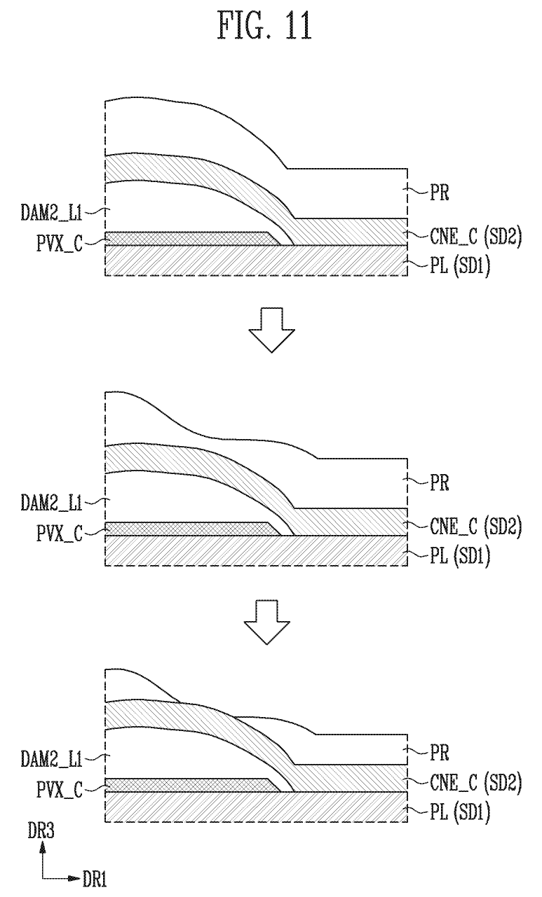

In one or more embodiments, in an area where the second dam DAM2 and the connection electrode CNE overlap, an opening OP_PVX (see FIG. 9) may be formed in the passivation layer PVX, or the passivation layer PVX may be partially absent. As will be described later with reference to FIGS. 10 and 11 , by removing the passivation layer PVX in the area where the second dam DAM2 and the connection electrode CNE overlap, particles (or residues) may be prevented or reduced from being generated during the process of forming the connection electrode CNE.

For example, as shown in FIG. 8, in an area where the power line PL (or a first electrode layer SD1, a first metal layer), the first layer DAM2_L1 of the second dam DAM2, and the connection electrode CNE (or a second electrode layer SD2, a second metal layer) overlap in the third direction DR3, the passivation layer PVX may not be present.

For example, in one or more embodiments, as shown in FIG. 9, in an area where the second dam DAM2 is located (or a second dam area A_DAM2 (see FIG. 7A)), an opening OP_PVX of the passivation layer PVX may be formed, or the passivation layer PVX may not be present. In these embodiments, as shown in FIG. 8, the first layer DAM2_L1 of the second dam DAM2 may be located directly on the power line PL (or the first electrode layer SD1).

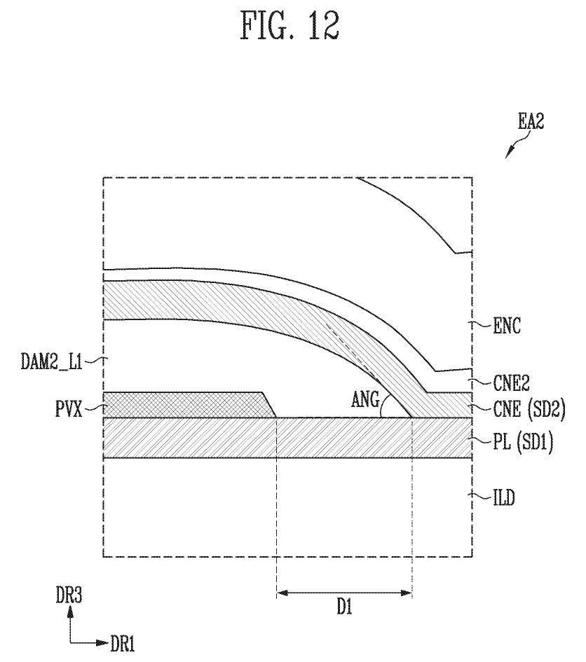

According to one or more embodiments, as shown in FIG. 7A, the first layer DAM2_L1 of the second dam DAM2 may be located directly on the power line PL and the interlayer insulating layer ILD. In FIG. 9, the second dam DAM2 and the passivation layer PVX are shown as fully non-overlapping, but embodiments of the present disclosure are not limited thereto. For example, in one or more embodiments, the second dam DAM2 and the passivation layer PVX may partially overlap (see FIGS. 12-15).

In one or more embodiments, when the passivation layer PVX is not present in the area where the second dam DAM2 and the connection electrode CNE overlap, a taper angle ANG of the first layer DAM2_L1 of the second dam DAM2 may be within a range of about 35 degrees to about 45 degrees. Here, the taper angle ANG (or inclination angle) may be an angle, at a point where the first layer DAM2_L1 and a base layer (e.g., the power line PL) underlying the first layer DAM2_L1 are in contact, between an inclined surface of the first layer DAM2_L1 and a top surface of the base layer. When the taper angle ANG is 45 degrees or less, particles of the connection electrode CNE (or the second electrode layer SD2) may not be generated. Considering limitations of width of the non-display area NDA (e.g., distance from the display area DA to the edge in the first direction DR1 with reference to FIG. 7A) and desired or required specifications (e.g., width and height) of the second dam DAM2, the taper angle ANG may be 35 degrees or greater.

As described above, in the area where the second dam DAM2 and the connection electrode CNE overlap, the opening OP_PVX may be formed in the passivation layer PVX, or the passivation layer PVX may be partially absent. Thus, particles (or residues) generated during the process of forming (or patterning) the connection electrode CNE and defects caused by the particles may be prevented or reduced, and the stability of the display device may be improved.

While the passivation layer PVX is shown arranged in an area (e.g., under the second dam DAM2) between the second dam DAM2 and the edge of the substrate SUB in FIG. 7A, the passivation layer PVX is not limited thereto. For example, in one or more embodiments, the passivation layer PVX may be removed (e.g., absent) from at least a portion of the area between the second dam DAM2 and the edge of the substrate SUB of FIG. 7A.

FIG. 10 is a cross-sectional view illustrating a comparative example of the area EA2 of FIG. 7A. FIG. 11 is a diagram illustrating the process of forming the connecting electrode of FIG. 10.

Referring to FIGS. 7A, 8, 10, and 11, except for a passivation layer PVX_C, the display device DD_C (or display panel DP_C) according to the comparative example is similar to the display device of FIGS. 7A, and 8 , and thus redundant description is not provided.

The passivation layer PVX_C may be arranged between the first layer DAM2_L1 of the second dam DAM2 and the power line PL (or the first electrode layer SD1). For example, the passivation layer PVX_C may be arranged to overlap with a slope of the first layer DAM2_L1 in the third direction DR3.

In an area where the passivation layer PVX_C and the first layer DAM2_L1 overlap, a connection electrode CNE_C (or a second electrode layer SD2_C) may be grooved, or the connection electrode CNE_C may be broken. Also, particles PTC may be present on the connection electrode CNE_C.

Referring to FIG. 11, a photoresist PR may be arranged on the second electrode layer SD2 for patterning the connection electrode CNE_C from the second electrode layer SD2. However, due to the height and slope of the first layer DAM2_L1 relative to the power line PL (or the first electrode layer SD1), the photoresist PR may flow down, and a portion of the second electrode layer SD2 may be exposed. In the process of etching the second electrode layer SD2, the portion of the second electrode layer SD2 may be unintentionally etched. For example, in the case that the second electrode layer SD2 includes aluminum (Al) or has a triple film structure of Ti/Al/Ti, substitution reaction of aluminum (Al) and silver (Ag) during wet etching process may cause aluminum (Al) to be lost from the portion of the second electrode layer SD2, and particles PTC including silver (Ag) may be generated. A plurality of particles PTC may be connected in the form of a line, connecting the connection electrode CNE_C with a different component and causing a short circuit failure.

Thus, the display device according to one or more embodiments of FIGS. 7A, and 8 may remove the passivation layer PVX in the area where the second dam DAM2 and the connection electrode CNE overlap, thereby reducing the taper angle ANG of the first layer DAM2_L1 and preventing or reducing particles (or residues) from being generated during the process of forming the connection electrode CNE.

FIG. 12 is a cross-sectional view illustrating an embodiment in which the area EA2 of FIG. 7A is enlarged according to one or more embodiments.

Referring now to FIGS. 7A, 8, and 12, except for the passivation layer PVX, the embodiment of FIG. 12 may be substantially the same or similar to the embodiment of FIG. 8. Accordingly, redundant description is not provided for conciseness.

The passivation layer PVX may be located in an area where the first layer DAM2_L1 of the second dam DAM2 and the power line PL overlap. The first layer DAM2_L1 of the second dam DAM2 may cover the passivation layer PVX (or an end or edge of the passivation layer PVX).

In one or more embodiments, the passivation layer PVX may be non-overlapping with a slope of the first layer DAM2_L1 in the third direction DR3. This is because if (e.g., when) the passivation layer PVX and the slope of the first layer DAM2_L1 overlap, the taper angle ANG of the first layer DAM2_L1 may be greater than a reference angle (e.g., 45 degrees).

The taper angle ANG may increase as the passivation layer PVX approaches one end of the first layer DAM2_L1. The one end of the first layer DAM2_L1 may be a point where a bottom surface and an inclined surface of the first layer DAM2_L1 meet, or a point where the power line PL and the connection electrode CNE are separated by the first layer DAM2_L1.

In one or more embodiments, the passivation layer PVX may be spaced apart from one end (or edge) of the first layer DAM2_L1 toward the edge of the substrate SUB by a first distance D1. Here, the first distance D1 is a shortest distance between the passivation layer PVX and the one end of the first layer DAM2_L1. For example, the first distance D1 may be greater than or equal to an average thickness in the third direction DR3 of the first layer DAM2_L1 (or the first via layer VIA1 in FIG. 7A), or greater than or equal to a distance in the third direction DR3 between the top surface and the bottom surface of the first layer DAM2_L1. In this regard, the taper angle ANG of the first layer DAM2_L1 may be less than the reference angle (e.g., 45 degrees).

In one or more embodiments of FIG. 8, the passivation layer PVX may be completely non-overlapping with the second dam DAM2, while in one or more embodiments of FIG. 12, the passivation layer PVX may partially overlap with the second dam DAM2, but the passivation layer PVX may be spaced apart from one end of the first layer DAM2_L1 of the second dam DAM2 by the first distance D1. Thus, particles (or residues) generated in the process of forming the connection electrode CNE and defects caused by the particles may be prevented or reduced, and the stability of the display device may be improved.

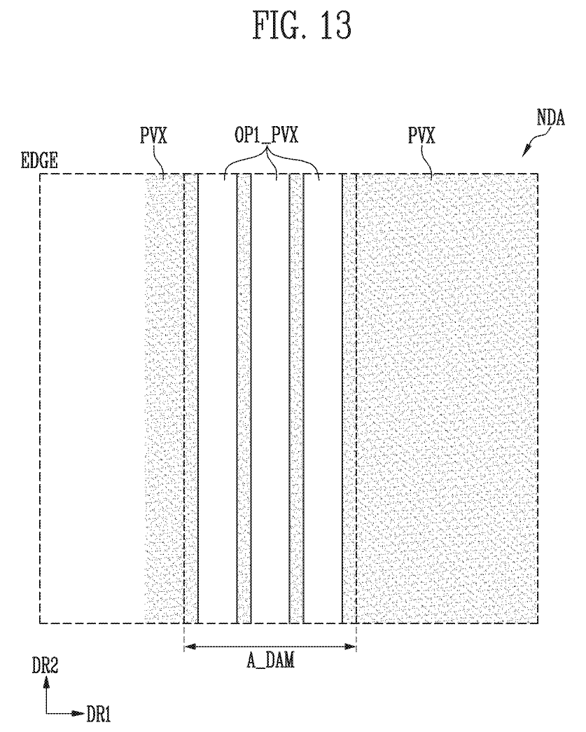

FIGS. 13, 14, and 15, are each a schematic plan view illustrating an embodiment of a non-display area of the display device of FIG. 7A according to one or more embodiments of the present disclosure. FIGS. 13, 14, and 15, illustrate one or more suitable shapes of first openings OP1_PVX of the passivation layer PVX.

Referring to FIGS. 7A, 8, 13, 14, and 15, except for shapes of the first openings OP1_PVX of the passivation layer PVX, the embodiments of FIGS. 13-15 may be substantially the same or similar to the embodiments of FIGS. 7A and 8. Accordingly, redundant description will not be provided for conciseness.

In the dam area A_DAM, the first openings OP1_PVX may be formed in the passivation layer PVX. Here, the dam area A_DAM may be an overlapping area with the second dam DAM2, or an overlapping area with the first dam DAM1 and the second dam DAM2.

Even in embodiments in which the first openings OP1_PVX are formed in the passivation layer PVX instead of the opening OP_PVX of FIG. 8, the first layer DAM2_L1 (see FIG. 7A) of the second dam DAM2 is filled with the first openings OP1_PVX, the height or taper angle of the first layer DAM2_L1 becomes smaller, and particles may not be generated. If (e.g., when) a total area of the first openings OP1_PVX is about 50% or more of the area of the dam area A_DAM, the taper angle ANG (see FIG. 8) of the first layer DAM2_L1 may be less than or equal to a reference angle (e.g., 45 degrees).

In one or more embodiments, as shown in FIG. 13, the first openings OP1_PVX may have a shape (e.g., a slit) extending in the second direction DR2 and may be arranged along the first direction DR1. Here, the second direction DR2 may be a direction parallel to the edge EDGE of the display panel (or an edge of the display area), and the first direction DR1 may be a direction intersecting the second direction DR2. The first direction DR1 and the second direction DR2 may vary depending on the location of the non-display area NDA (e.g., left, right, or top of the display panel).

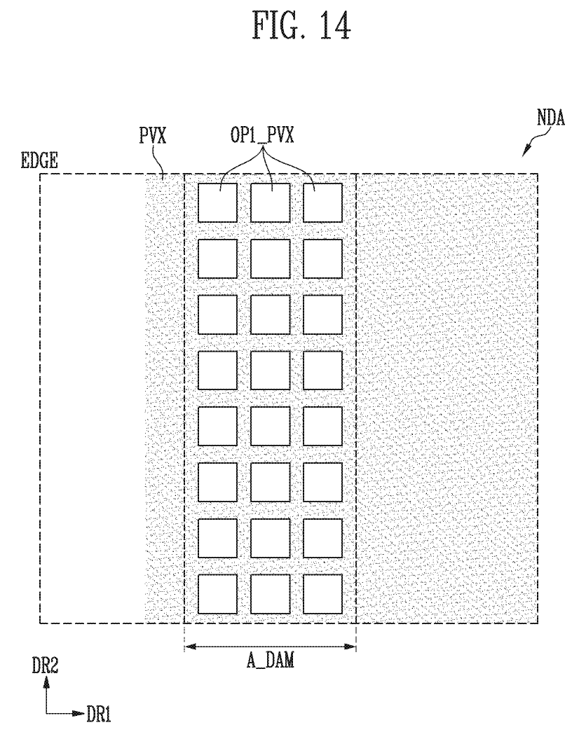

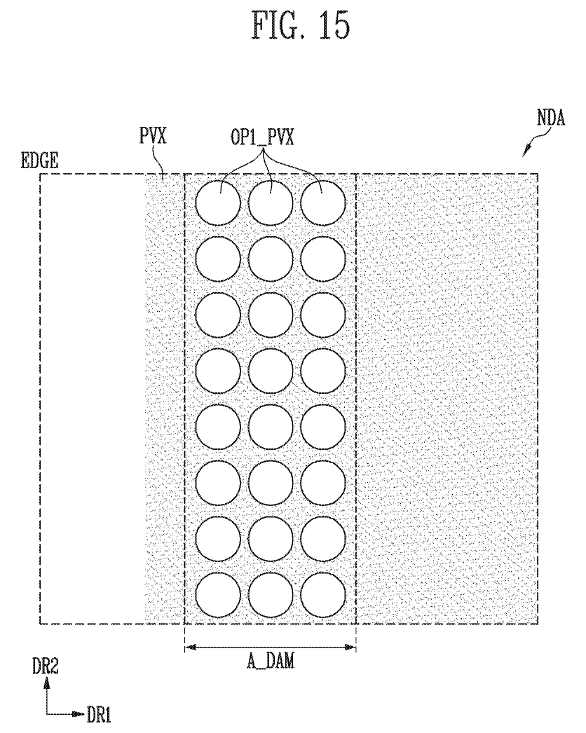

In one or more embodiments, as shown in FIGS. 14, and 15 , the first openings OP1_PVX each have an island shape (e.g., each opening is an isolated, discrete region surrounded by the first insulating layer without any direct connection to adjacent openings) and may be arranged in a matrix form (e.g., the openings are positioned in a regular grid pattern along two intersecting directions). For example, the first openings OP1_PVX may be arranged along the first direction DR1 and the second direction DR2 (e.g., to form rows and columns of evenly spaced openings). For example, in one or more embodiments, as shown in FIG. 14, each of the first openings OP1_PVX may have a rectangular planar shape. For example, in one or more embodiments, as shown in FIG. 15, each of the first openings OP1_PVX may have a circular planar shape. However, the first openings OP1_PVX are not limited thereto, and the shape of each of the first openings OP1_PVX may be varied as desired or suitable without limitation.

The display device according to one or more embodiments may be applied to one or more suitable electronic devices. An electronic device according to one or more embodiments may include the display device described above and may further include modules or devices having other additional functions in addition to the display device.

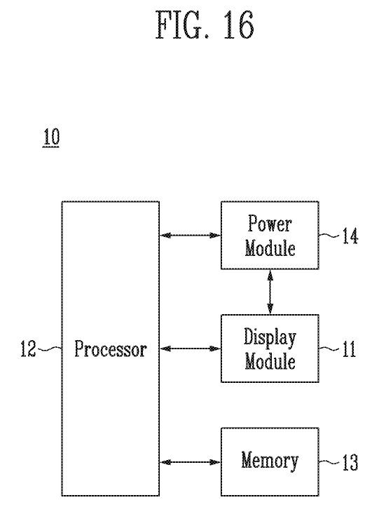

FIG. 16 is a block diagram of an electronic device according to one or more embodiments of the present disclosure. Referring to FIG. 16, an electronic device 10 according to one or more embodiments may include a display module 11 (or display device), a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information necessary for operations of the processor 12 and/or the display module 11. When the processor 12 executes an application stored in the memory 13, image data signals and/or input control signals are delivered to the display module 11, and the display module 11 may process the received signals to output image information via a display screen.

The power module 14 may include a power supply module, such as a power adapter or a battery unit, and a power conversion module that converts power supplied by the power supply module to generate power desired or required for operation of the electronic device 10.

At least one of the above-described components of the electronic device 10 may be included within the display device according to one or more embodiments. Furthermore, some of the individual modules that are functionally included in one module may be included in the display device and others may be provided separately from the display device. For example, the display device may include the display module 11, while the processor 12, the memory 13, and the power module 14 may be provided in the form of other devices in the electronic device 10 other than the display device.

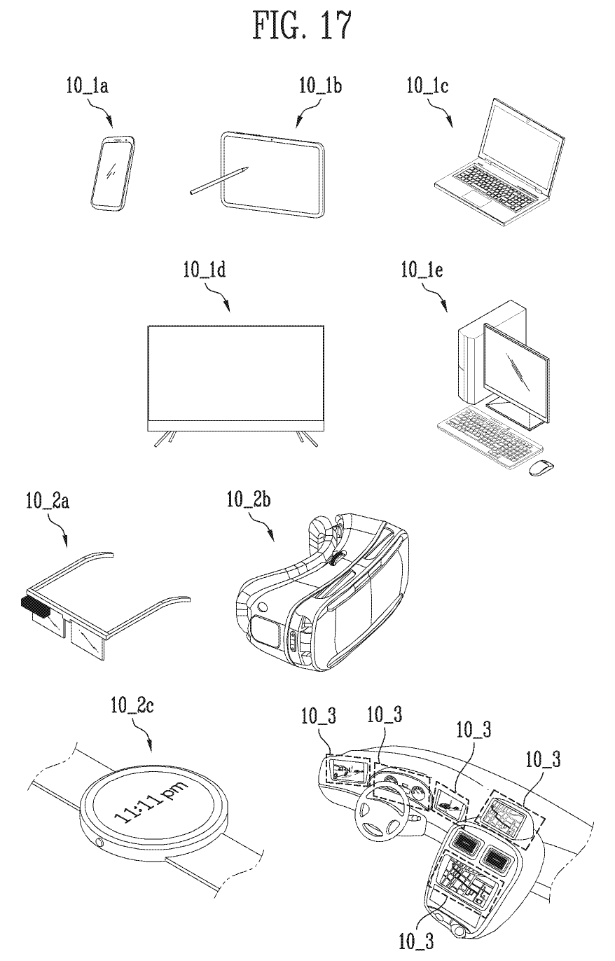

FIG. 17 is a schematic diagram of illustrating various electronic devices according to one or more embodiments of the present disclosure.

Referring now to FIG. 17, one or more suitable electronic devices with a display device according to one or more embodiments include an electronic device for displaying images, such a as a smartphones 10_1a, a tablet PC 10_1b, a laptop 10_1c, a television 10_1d, a desk monitor 10_1e, as well as a wearable electronic device including a display module such as a smart glasses 10_2a, a head-mounted display 10_2b, a smart watch 10_2c, and/or the like, and an automotive electronic device 10_3 including a display module such as a center information display (CID), a room mirror display, and/or the like arranged on an instrument panel, a center fascia, or a dashboard of an automobile.

In the context of the present application and unless otherwise defined, the terms "use," "using," and "used" may be considered synonymous with the terms "utilize," "utilizing," and "utilized," respectively.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device, the electronic devices/apparatus, the display device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

While certain technical aspects of the present disclosure have been specifically described according to one or more embodiments described above, it should be noted that the embodiments are for illustration purposes only and are not intended to be limiting. Furthermore, those skilled in the art will understand that one or more suitable modifications are possible within the scope of the technical concept of the present disclosure.

It is further understood that the scope of the disclosure should not be limited to the content described in the detailed description of the disclosure, but should be defined by the appended claims and equivalents thereof. All modifications or variations derived from the meaning and scope of the claims, and their equivalents, should be interpreted as being included within the scope of the disclosure.

What is claimed is:

1. A display device, comprising:
a first electrode layer on a substrate;
a first insulating layer on the first electrode layer;
a second insulating layer on the first insulating layer;
a second electrode layer on the second insulating layer;
a third insulating layer on the second electrode layer;
a light emitting element on the third insulating layer; and
a dam along an edge of the substrate,
wherein the dam comprises:
a first layer comprising a same material as the second insulating layer; and
a second layer comprising a same material as the third insulating layer,
wherein the first layer of the dam is located between the first electrode layer and the second electrode layer, and
wherein, in an area where the first layer of the dam and the second electrode layer overlap, an opening is formed in the first insulating layer.

2. The display device of claim 1, wherein the first insulating layer comprises an inorganic material, and
wherein the second insulating layer and the third insulating layer each comprise an organic material.

3. The display device of claim 2, wherein the first insulating layer is absent throughout an area in which the dam is located.

4. The display device of claim 2, wherein a taper angle of the first layer of the dam at the opening is within a range of 35 degrees to 45 degrees.

5. The display device of claim 2, wherein the first insulating layer is partially absent in an area where a slope of the first layer of the dam is located.

6. The display device of claim 2, wherein the first insulating layer is apart from an edge of the first layer of the dam located in the opening toward an edge of the substrate by a first distance, and
wherein the first distance is greater than or equal to a height of the first layer of the dam.

7. The display device of claim 1, wherein a plurality of openings are formed in the first insulating layer in an area where the dam is located, and
wherein a total area of the plurality of openings is at least 50% of the area in which the dam is located.

8. The display device of claim 7, wherein the plurality of openings each have a shape extending in a second direction parallel to an edge of the substrate, and are arranged with one another along a first direction intersecting the second direction.

9. The display device of claim 7, wherein each of the plurality of openings has an island shape and is arranged in a matrix.

10. The display device of claim 9, wherein each of the plurality of openings has a rectangular planar shape.

11. The display device of claim 9, wherein each of the plurality of openings has a circular planar shape.

12. The display device of claim 1, further comprising:
a first conductive layer on the substrate;
a fourth insulating layer on the first conductive layer;
a second conductive layer on the fourth insulating layer; and
a fifth insulating layer on the second conductive layer,
wherein the first electrode layer is on the fifth insulating layer,
wherein fan-out lines, which extend from an edge of the substrate toward a display area in which the light emitting element is located, are located in the first conductive layer, the second conductive layer, and the first electrode layer,
wherein a power line, which is configured to receive a constant voltage and overlap with the fan-out lines, is located in the second electrode layer, and
wherein the second insulating layer is not present between the fan-out lines and the power line.

13. The display device of claim 1, wherein the first insulating layer is in an area between the dam and an edge of the substrate.

14. The display device of claim 13, wherein, in an area between the dam and the edge of the substrate, the first insulating layer overlaps with a conductive pattern located under the first insulating layer.

15. An electronic device, comprising:
a display panel configured to display an image in a display area; and
a window on the display panel and comprising:
a transparent area overlapping the display area; and
a light shielding area around the transparent area,
wherein the display panel comprises:
a first electrode layer on a substrate;
a first insulating layer on the first electrode layer;
a second insulating layer on the first insulating layer;
a second electrode layer on the second insulating layer;
a third insulating layer on the second electrode layer;
a light emitting element on the third insulating layer; and
a dam that overlaps with the light shielding area,
wherein the dam comprises:
a first layer comprising a same material as the second insulating layer; and
a second layer comprising a same material as the third insulating layer,
wherein the first layer of the dam is located between the first electrode layer and the second electrode layer, and
wherein, in an area where the first layer of the dam and the second electrode layer overlap, an opening is formed in the first insulating layer.

16. The electronic device of claim 15, wherein the first insulating layer comprises an inorganic material, and
wherein the second insulating layer and the third insulating layer each comprise an organic material.

17. The electronic device of claim 16, wherein the first insulating layer is absent throughout an area in which the dam is located.

18. The electronic device of claim 16, wherein a taper angle of the first layer of the dam at the opening is within a range of 35 degrees to 45 degrees.

19. The electronic device of claim 15, wherein a plurality of openings are formed in the first insulating layer in an area where the dam is located, and
wherein a total area of the plurality of openings is at least 50% of the area in which the dam is located.

20. The electronic device of claim 15, wherein the display panel further comprises:
a first conductive layer on the substrate;
a fourth insulating layer on the first conductive layer;
a second conductive layer on the fourth insulating layer; and
a fifth insulating layer on the second conductive layer,
wherein the first electrode layer is on the fifth insulating layer,
wherein fan-out lines, which extend from an edge of the substrate toward the display area in which the light emitting element is located, are located in the first conductive layer, the second conductive layer, and the first electrode layer,
wherein a power line, which is configured to receive a constant voltage and overlap with the fan-out lines, is located in the second electrode layer, and
wherein the second insulating layer is not present between the fan-out lines and the power line.
